(19) United States
(12) Patent Application Publication
(10) Pub. No.: US 2014/0374848 A1
(43) Pub. Date: Dec. 25, 2014

(54) SEMICONDUCTOR SENSOR DEVICE WITH METAL LID

(71) Applicants: Wen Shi Koh, Petaling Jaya (MY); Wai Yew Lo, Petaling Jaya (MY); Kong Bee Tiu, Port Klang (MY)

(72) Inventors: Wen Shi Koh, Petaling Jaya (MY); Wai Yew Lo, Petaling Jaya (MY); Kong Bee Tiu, Port Klang (MY)

(21) Appl. No.: 13/924,628

(22) Filed: Jun. 24, 2013

(51) Int. Cl. H01L 41/053

(52) U.S. Cl. CPC H01L 41/053
USPC 257/415

(57) ABSTRACT

A semiconductor sensor device is packaged using a lid in which one or more dies are mounted to a substrate within the lid housing and one or more other dies are mounted to the substrate outside of the lid housing. The dies located outside of the lid housing may be encapsulated in a molding compound. In one embodiment, the lid has a vent hole and an active region of a pressure-sensing die located inside the lid housing is covered by a pressure-sensitive gel that together enable ambient atmospheric pressure immediately outside the sensor device to reach the active region of the pressure-sensing die. The sensor device may also have one or more other types of sensor dies, such as an acceleration-sensing die, to form a multi-sensor device.

### BACKGROUND OF THE INVENTION

The present invention relates generally to semiconductor sensor devices, and more particularly to semiconductor pressure sensors.

Semiconductor sensor devices such as pressure sensors are well known. Such devices use semiconductor pressure-sensing dies. These dies are susceptible to mechanical damage during packaging and environmental damage when in use, and thus they must be carefully packaged. Further, pressure-sensing dies, such as piezo resistive transducer (PRT) and parameterized layout cell (P-cell), do not allow full encapsulation because that would impede their functionality. In conventional pressure sensor packages, the pressure-sensing die typically is mounted in a cavity of a pre-molded lead frame, and the cavity and die are then covered with a separate cover or lid. However, the lead frame pre-molding process is not robust, often having a low yield and mold-related defects. Packages with pre-molded lead frames or pre-molded substrates have other associated issues such as mold flashing and voids, mold-die paddle co-planarity, and cavity-height inconsistency.

Accordingly, it would be advantageous to have a more reliable and economical way to package dies in semiconductor sensor devices.

### BRIEF DESCRIPTION OF THE DRAWINGS

Embodiments of the present disclosure are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIGS. 1A and 1B respectively show a cross-sectional side view and a cross-sectional top plan view of a packaged semiconductor sensor device in accordance with an embodiment of the disclosure;

FIGS. 2(A)-2(I) show cross-sectional side views that illustrate the steps of an exemplary method of manufacturing multiple instances of the sensor device of FIG. 1;

FIGS. 3(A) and 3(B) respectively show a cross-sectional side view and a cross-sectional top plan view of a packaged semiconductor sensor device in accordance with another embodiment of the disclosure;

FIGS. 4(A)-4(I) show cross-sectional side views that illustrate the steps of an exemplary method of manufacturing multiple instances of the sensor device of FIG. 3; and

FIGS. 5(A) and 5(B) respectively show a cross-sectional side view and a cross-sectional top plan view of a packaged semiconductor sensor device in accordance with yet another embodiment of the disclosure.

### DETAILED DESCRIPTION OF THE INVENTION

Detailed illustrative embodiments of the present disclosure are disclosed herein. However, specific structural and functional details disclosed herein are merely representative for purposes of describing example embodiments of the present disclosure. Embodiments of the present disclosure may be embodied in many alternative forms and should not be construed as limited to only the embodiments set forth herein. Further, the terminology used herein is for the purpose of describing particular embodiments only and is not intended to be limiting of example embodiments of the disclosure.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment of the disclosure, a semiconductor sensor device comprises a substrate, a pressure-sensing die mounted to the substrate, pressure-sensitive gel covering at least part of the pressure-sensing die, a lid (i) mounted to the substrate to form a housing for the gel-covered pressure-sensing die and (ii) having an opening that exposes the gel-covered pressure-sensing die to ambient atmospheric pressure outside the sensor device, at least one other die mounted outside of the housing, and molding compound encapsulating the at least one other die.

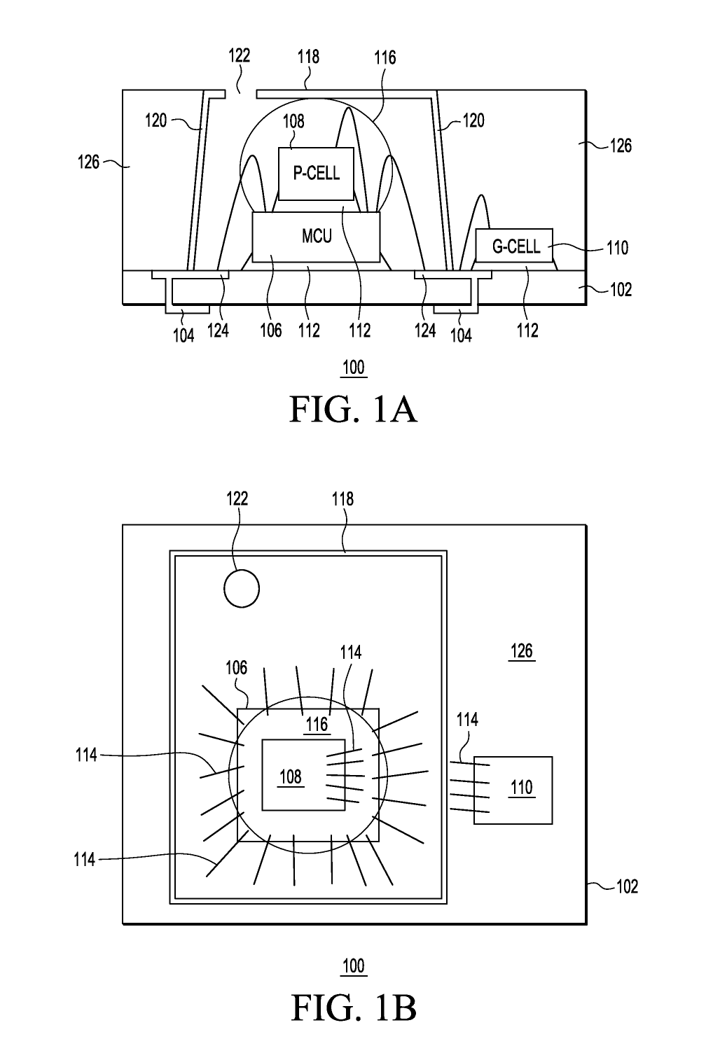

FIGS. 1A and 1B respectively show a cross-sectional side view and a cross-sectional top plan view of a packaged semiconductor sensor device 100 in accordance with an embodiment of the disclosure. Packaged semiconductor sensor device 100 includes an insulating (e.g., bare silicon) substrate 102 with conducting lead fingers 104. The lead fingers may be formed of copper, an alloy of copper, a copper plated iron/nickel alloy, plated aluminum, or the like.

An application-specific integrated circuit (ASIC) die 106 is mounted to (e.g., physically attached and electrically coupled to) substrate 102. The ASIC die 106 functions as the master control unit (MCU) for sensor device 100 and is synonymously referred to herein as MCU 106. A pressure-sensing die (a.k.a. P-cell) 108, designed to sense ambient atmospheric pressure, is mounted to the MCU 106. Also mounted to substrate 102 is an acceleration-sensing die (a.k a. G-cell) 110, designed to sense gravity or acceleration in one, two, or all three axes, depending on the particular implementation. Although the first or bottom die 106 shown in the drawings is described herein as an ASIC die or MCU, this die does not have to be an application specific IC; rather, the die could be a controller or microcontroller die programmed to operate with the sensor die 110.

Conventional die-attach adhesive 112 may be used to attach (i) MCU 106 and G-cell 110 to substrate 102 and (ii) P-cell 108 to MCU 106. Those skilled in the art will understand that suitable alternative means, such as die-attach tape, may be used to attach some or all of these dies. Substrate 102, MCU 106, P-cell 108, and G-cell 110 are well known components of semiconductor devices and thus detailed descriptions thereof are not necessary for a complete understanding of the disclosure.

Bond wires 114 are wire-bonded between (i) bond pads on P-cell 108 and (ii) corresponding bond pads on MCU 106 using a suitable, known wire-bonding process and suitable, known wire-bonding equipment to provide the electrical interconnection between P-cell 108 and MCU 106. Similarly, the electrical interconnection between G-cell 110 and MCU 106 is provided by (i) wire-bonding between other bond pads on MCU 106 and corresponding lead fingers 104 of substrate 102 and (ii) wire-bonding between bond pads on G-cell 110 and the same or other corresponding lead fingers 104 of substrate 102. Bond wires 114 are formed from a conductive material such as aluminium, gold, or copper, and may be either coated or uncoated.

A pressure-sensitive gel material 116, such as a silicon-based gel, is deposited on top of P-cell 108 such that the gel material covers at least the pressure-sensitive active region on the top side of the P-cell. In the implementation of FIG. 1, gel material 116 also covers the wire-bonded bond pads of P-cell 108 and is deposited around the sides of P-cell 108 in a manner that surrounds P-cell 108 and also covers the wire-bonded bond pads of MCU 106. Note that, in the particular implementation shown in FIG. 1, the pressure-sensitive gel surrounds the entire lengths of the bond wires between P-cell 108 and MCU 106, but only part of the lengths of the bond wires between MCU 106 and substrate 102.

Pressure-sensitive gel 116 enables the pressure of the ambient atmosphere to reach the pressure-sensitive active region of P-cell 108, while protecting P-cell 108 and its wire-bonding from mechanical damage during packaging and environmental damage (e.g., contamination and/or corrosion) when in use. Examples of suitable pressure-sensitive gel 116 are available from Dow Corning Corporation of Midland, Mich.

A footed lid 118 having slanted side walls 120, an opening or vent hole 122, and fan-out metal lid legs 124, is mounted to substrate 102 over the gel-covered P-cell/MCU sub-assembly to provide a protective housing surrounding that sub-assembly. In this exemplary implementation, side walls 120 are attached to substrate 102 with a suitable, conventional lid-attach adhesive such as a non-conductive epoxy. Lid 118 and substrate 102 form a cavity or housing within which the gel-covered P-cell and MCU sub-assembly is located. Fan-out legs 124 and lead fingers 104 enable electrical connections between dies located inside the lid housing (e.g., MCU 106) and dies located outside the lid housing (e.g., G-cell 110). Lead fingers 104 also enable sensor device 100 to be electrically connected to other, external elements and components (e.g., a printed circuit board).

The vent hole 122 allows the ambient atmospheric pressure immediately outside sensor device 100 to reach (i) the pressure-sensitive gel 116 and therethrough (ii) the active region of P-cell 108. The vent hole 122 can be located anywhere within the area of lid 118. The vent hole 122 may be (pre-)formed in the lid by a known fabrication process such as drilling or punching.

Although in a preferred embodiment the lid 118 is formed of metal, this is not required; rather, the lid 118 need only be formed of a durable and stiff material, such as stainless steel, plated metal, or polymer, so that P-cell 108 and MCU 106 are protected. The lid 118 is sized and shaped depending on the number and size of the dies mounted to the substrate under the lid 118. Accordingly, depending on the implementation, the lid 118 may have any suitable shape, such as round, square, or rectangular.

A molding compound 126 applied up to the height of lid 118 covers and encapsulates G-cell 110, its wire bonding, and everything else in sensor device 100 that is located outside of the lid housing. Note that, because lid 118 has side walls 120 that slant outward, molding compound 126 helps to retain lid 118 in place on substrate 102. The molding compound may be a plastic, an epoxy, a silica-filled resin, a ceramic, a halide-free material, the like, or combinations thereof, as is known in the art.

The exemplary configuration of sensor device 100 forms a no-leads type package such as a quad flat no-leads (QFN) package. In certain exemplary implementations, substrate 102 is a flexible or a laminated substrate that can prevent leakage of gel material 116 from sensor device 100.

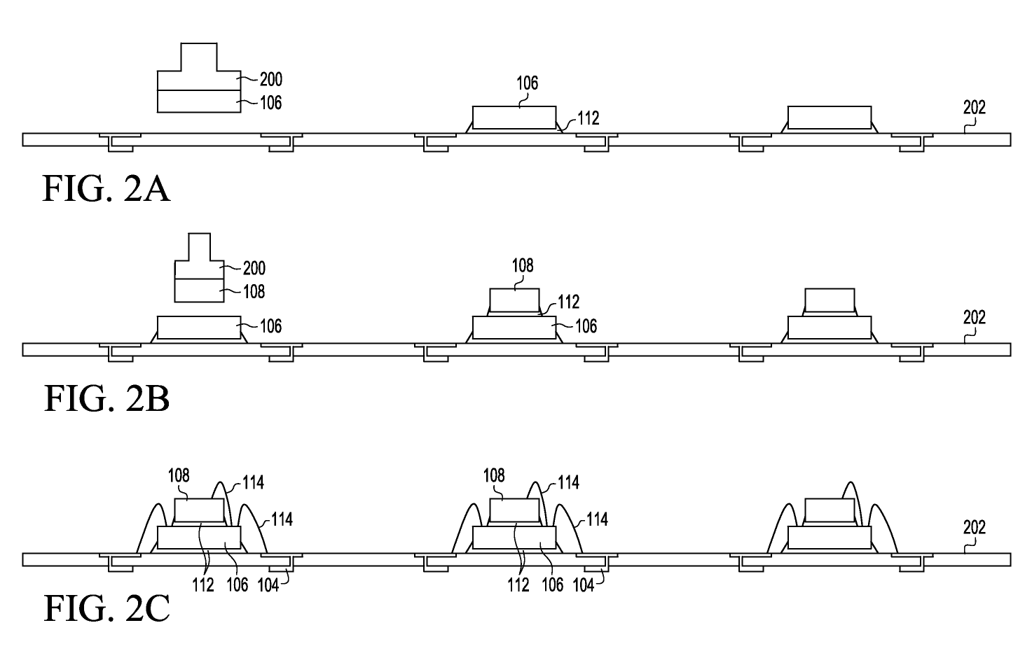

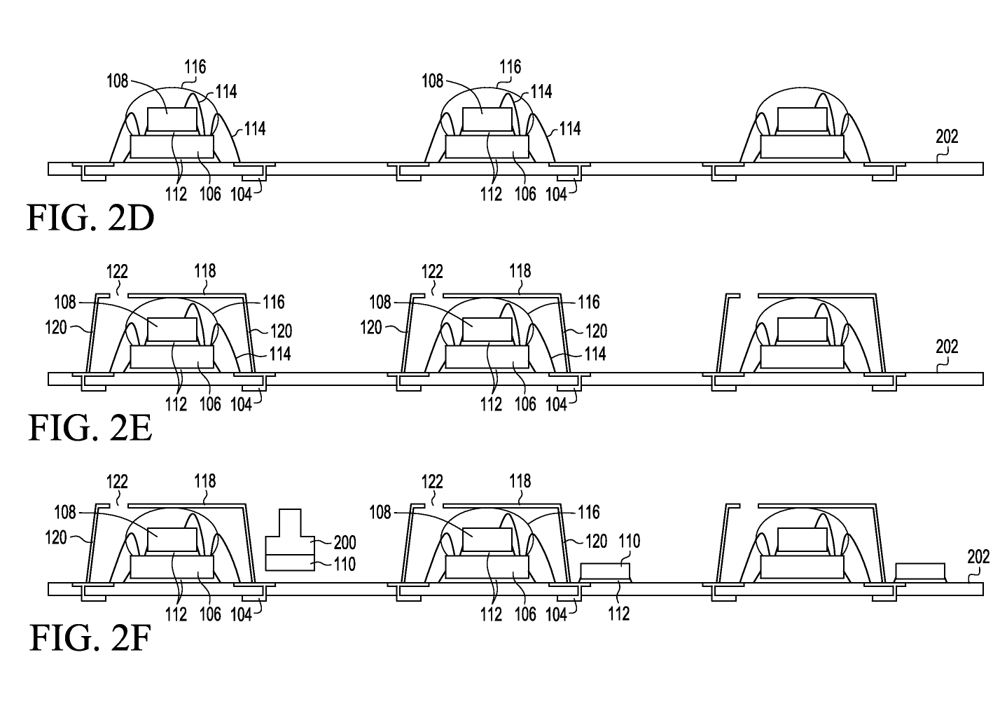

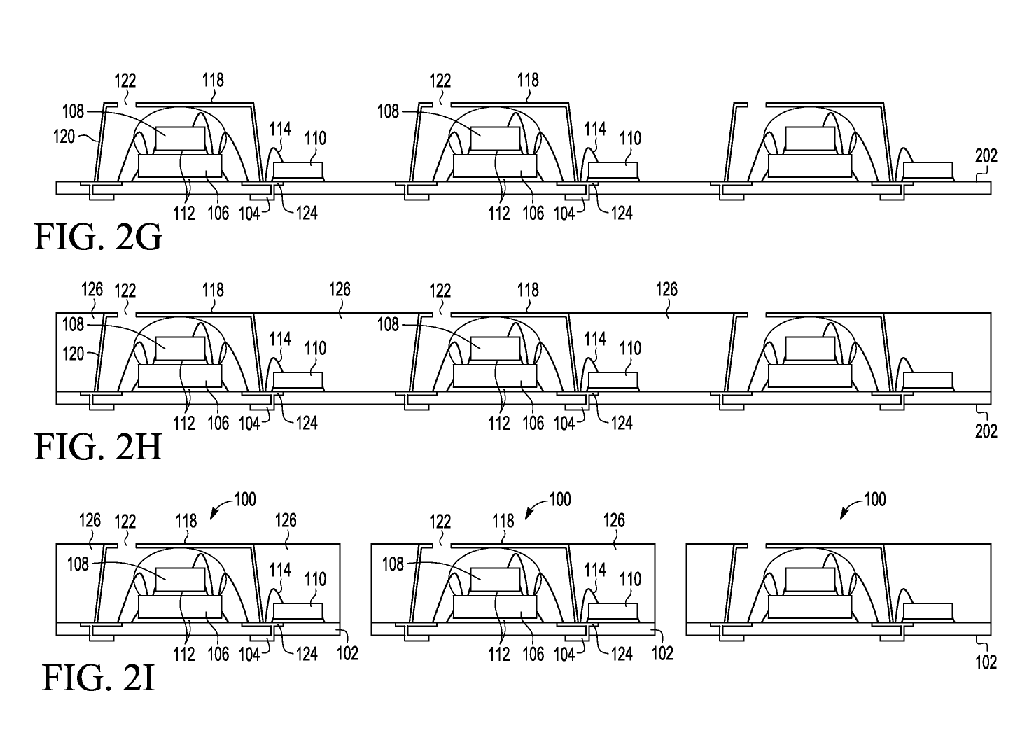

FIGS. 2A-2I show cross-sectional side views that illustrate the steps of an exemplary method of manufacturing multiple instances of sensor device 100 of FIG. 1.

FIG. 2A illustrates the step of conventional pick-and-place machinery 200 attaching multiple instances of MCU 106 to substrate disc 202 for a one- or two-dimensional array of sensor devices. The MCU dies are attached to respective locations on substrate disc 202 using die-attach adhesive 112 such as a suitable die-bonding epoxy. Die-attach adhesive 112 is dispensed on a top surface of substrate disc 202 using a known dispensing device (not shown), and machinery 200 places the MCU dies on the die-attach adhesive to attach the MCU dies to corresponding locations on the substrate disc. The die-attach adhesive may subsequently be cured in an oven or via light waves to harden the die-attach adhesive.

Analogous to the step of FIG. 2A, FIG. 2B illustrates the step of pick-and-place machinery 200 attaching multiple instances of P-cell 108 to corresponding instances of MCU 106, again using die-attach adhesive 112.

FIG. 2C illustrates the step of wire-bonding bond wires 114 to electrically connect (i) the P-cell dies 108 to the corresponding MCU dies 106 and (ii) the MCU dies 106 to corresponding lead fingers 104 on substrate disc 202.

Another way of electrically connecting a semiconductor die is through flip-chip bumps (not shown) attached to an underside of the semiconductor die. The flip-chip bumps may include solder bumps, gold balls, molded studs, or combinations thereof. The bumps may be formed or placed on the semiconductor die using known techniques such as evaporation, electroplating, printing, jetting, stud bumping, and direct placement. The semiconductor die is flipped, and the bumps are aligned with corresponding contact pads (not shown) of the structure (e.g., the substrate or another die) to which the die is mounted.

FIG. 2D illustrates the step of dispensing gel material 116 onto and around the P-cell dies 108. The gel material may be dispensed with a nozzle of a conventional dispensing machine, as is known in the art.

FIG. 2E illustrates the step of attaching a respective lid 118 over each P-cell/MCU sub-assembly using a suitable lid-attach adhesive (not shown). The lid-attach adhesive is dispensed on a top surface of the lead fingers 104 using a known dispensing device, and the side walls 120 are placed on the lid-attach adhesive to attach the side walls to the respective lead fingers. The lid-attach adhesive is subsequently cured in an oven.

Analogous to the steps of FIGS. 2A and 2B, FIG. 2F illustrates the step of pick-and-place machinery 200 attaching multiple instances of G-cell 110 to corresponding locations on substrate disc 202, again using die-attach adhesive 112.

Analogous to FIG. 2C, FIG. 2G illustrates the step of wire-bonding bond wires 114 to electrically connect the G-cell dies 110 to corresponding fan-out legs 124 of lids 118 and/or to corresponding lead fingers 104 on substrate disc 202.

FIG. 2H illustrates the step of applying molding compound 126 onto substrate disc 202 in regions that are outside of the lid housings up to the height of lids 118. The molding material covers the G-cell dies 110, their corresponding bond wires 114, and anything else located outside of the lid housings. One way of applying the molding compound is using a nozzle of a conventional dispensing machine, as is known in the art.

The molding material is typically applied as a liquid polymer, which is then heated to form a solid by curing in a UV or ambient atmosphere, whereby an array of semiconductor sensor devices is formed on substrate disc 202. The molding material can also be a solid that is heated to form a liquid for application and then cooled to form a solid mold. In alternative embodiments, other encapsulating processes may be used. Subsequently, an oven is used to cure the molding material to complete the cross linking of the polymer.

FIG. 2I illustrates the step of the individual semiconductor sensor devices 100 being separated from each other by a singulation process. Singulation processes are well known and may include cutting substrate disc 202 with a saw or a laser.

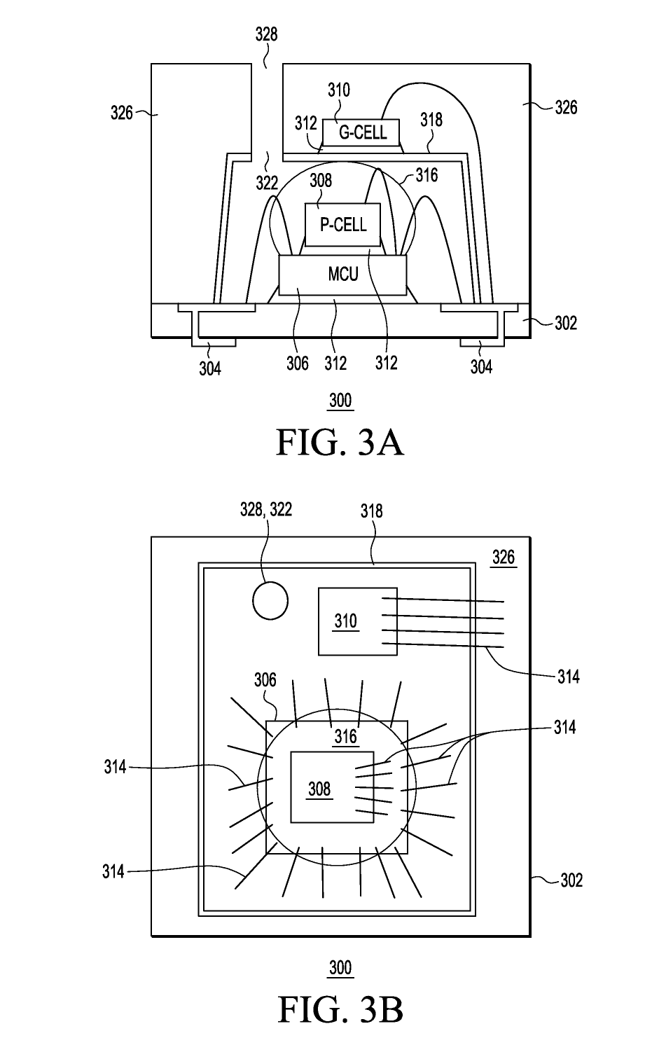

FIGS. 3A and 3B respectively show a cross-sectional side view and a cross-sectional top plan view of a packaged semiconductor sensor device 300 in accordance with another embodiment of the disclosure. Packaged semiconductor sensor device 300 is similar to packaged semiconductor sensor device 100 of FIG. 1, except that, instead of being mounted directly to substrate 302, G-cell 310 is mounted on top of lid 318 with bond wires 314 providing the electrical connection between the G-cell and the substrate.

As shown in FIG. 3A, in order to encapsulate G-cell 310, the level of molding compound 326 extends above the height of lid 318. Furthermore, in addition to there being a vent hole 322 in lid 318, there is also a corresponding opening or vent hole 328 in molding compound 326 to enable ambient atmospheric pressure immediately outside of sensor device 300 to reach P-cell BD. Vent holes 322 and 326 can be co-located anywhere within the area of lid 318, so long as the holes do not interfere with G-cell 310.

Although the overall height of sensor device 300 is greater than that of a comparable implementation of sensor device 100 of FIG. 1, the layout area of sensor device 300 can be smaller than that of sensor device 100 as a result of the mounting of G-cell 310 on top of lid 318.

Note that comparable implementations of sensors 100 and 300 use substantially identical amounts of gel material (116 and 316, respectively).

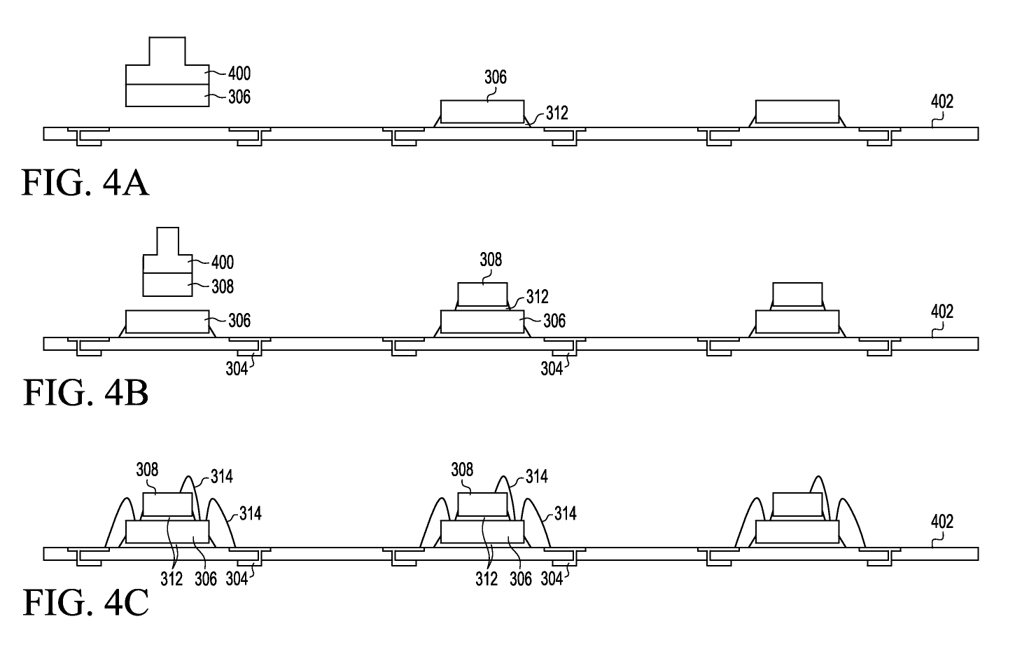

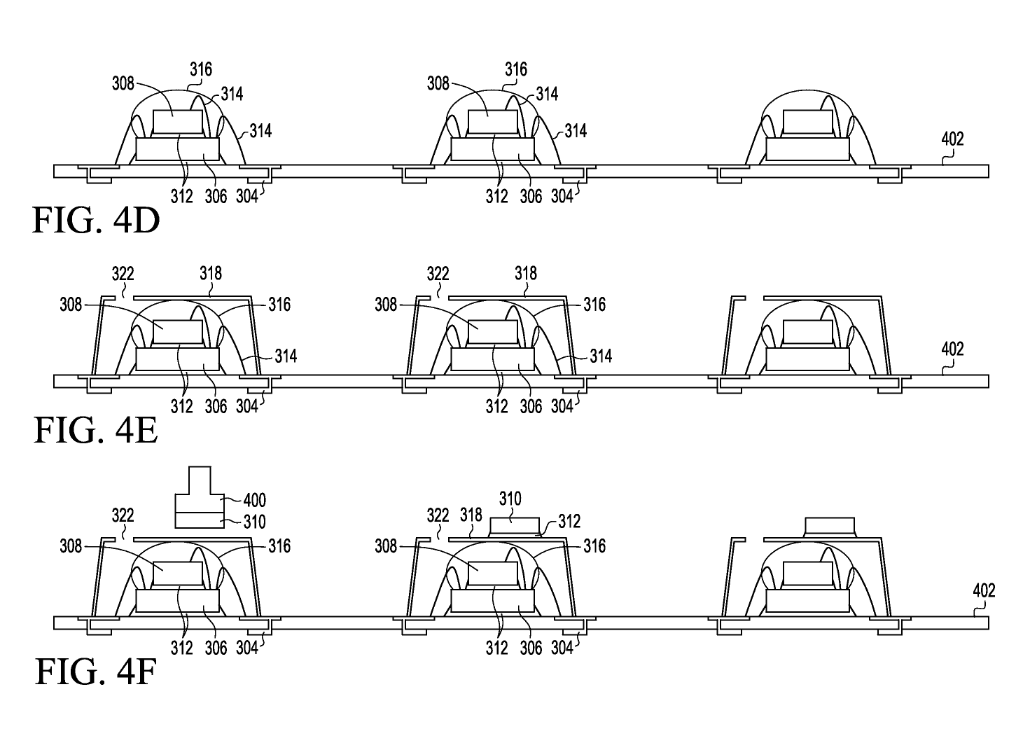

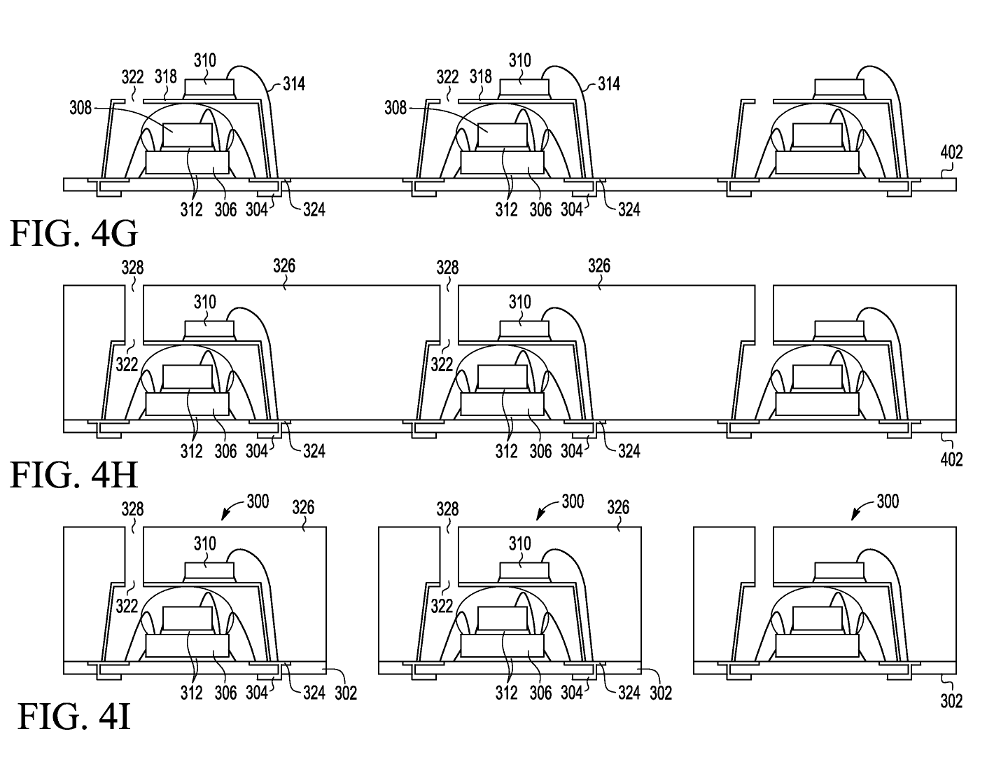

FIGS. 4A-4I show cross-sectional side views that illustrate the steps of an exemplary method of manufacturing multiple instances of sensor device 300 of FIG. 3. The steps of FIGS. 4A-4E for sensor device 300 are identical to the steps of FIGS. 2A-2E for sensor device 100.

FIG. 4F illustrates the step of pick-and-place machinery 400 mounting multiple instances of G-cell 310 to corresponding locations on the tops of lids 318, using die-attach adhesive 312.

FIG. 4G illustrates the step of wire-bonding bond wires 314 to electrically connect the G-cell dies 310 to corresponding fan-out legs 324 and/or lead fingers 304 on substrate disc 402. Note that longer bond wires are used to connect the G-cell dies to the substrate in sensor device 300 than in a comparable implementation of sensor device 100.

FIG. 4H illustrates the step of applying molding material 326 onto substrate disc 402 up to a level sufficient to encapsulate G-cell dies 310 mounted to the tops of lids 318. In one implementation, holes 328 are formed in molding compound 326 using pin molding, in which a respective cylindrical pin having a diameter substantially equal to or slightly smaller than the diameter of vent hole 322, is placed over or into each vent hole 322 as the molding compound is applied and then removed after the molding compound is cured. In this way, holes 328 are created, and the molding compound is prevented from leaking into the cavities created by lids 318.

FIG. 4I illustrates the individual semiconductor sensor devices 300 being separated from each other by a singulation process.

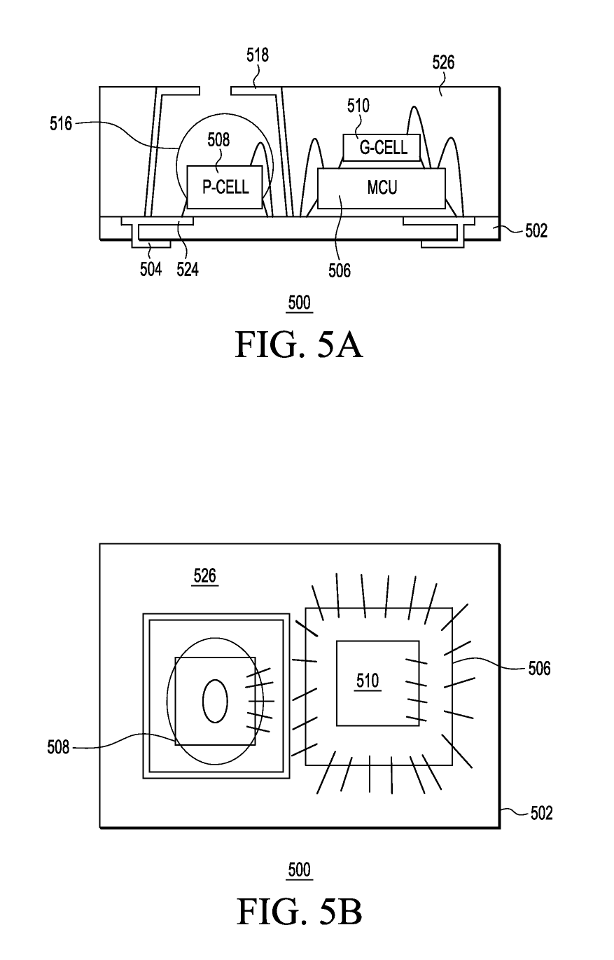

FIGS. 5A and 5B respectively show an cross-sectional side view and an cross-sectional top plan view of a packaged semiconductor sensor device 500 in accordance with yet another embodiment of the disclosure. Packaged semiconductor sensor device 500 is similar to packaged semiconductor sensor device 100 of FIG. 1, except that MCU 506 is mounted to substrate 502 outside of lid housing 518 and under G-cell 510, and P-cell 508 is mounted directly to substrate 502.

Although not explicitly shown in figures, those skilled in the art will understand that the steps used to manufacture sensor device 500 of FIG. 5 are similar or analogous to corresponding steps used to manufacture sensor devices 100 and/or 300.

Note that, because MCU 506 is located outside of lid housing 518, less pressure-sensitive gel material is required in sensor device 500 than in comparable implementations of sensor devices 100 and 300. Note further that, since lid 518 needs to cover only P-cell 508, instead of a stacked P-cell/MCU sub-assembly, the height of lid 518 and therefore the overall height of sensor device 500 can be less than that of comparable implementations of sensor devices 100 and 300. As a result, the amount of molding compound 126 used in sensor device 500 can also be less than that used for comparable implementations of sensor devices 100 and 300.

Although the disclosure has been described in the context of packaged semiconductor sensor devices having, in addition to an MCU ASIC die, both a pressure-sensing P-cell die and an acceleration-sensing G-cell die, other configurations of sensor devices are also possible. For example, in addition to or instead of a G-cell, a sensor device could have one or more other types of sensing dies, each designed to sense a characteristic other than acceleration. Each other sensor die could be respectively mounted either outside or inside of the lid housing as long as the sensor device has at least one die mounted inside the lid housing and at least one other die mounted outside the lid housing.

Although the disclosure has been described in the context of multi-sensor devices designed to sense multiple characteristics, such as pressure and acceleration, single-sensor devices are also possible. For example, a sensor device that senses only pressure could have a P-cell mounted inside the lid housing and an MCU mounted outside the lid housing, with no other sensing dies. One possible implementation of such a pressure-only sensor device could be the sensor device shown in FIG. 5 with G-cell 510 omitted.

As used herein, the term “mounted to” as in “a first die mounted to a substrate” covers situations in which the first die is mounted directly to the substrate with no other intervening dies (as in the mounting of G-cell 110 to substrate 102 in FIG. 1) as well as situations in which the first die is directly mounted to another die, which is itself mounted directly to the substrate (as in the mounting of P-cell 108 to substrate 102 in FIG. 1). Note that “mounted to” also covers situations in which there are two or more intervening dies between the first die and the substrate.

Sensor devices 100, 300, and 500 can all be made smaller (e.g., footprint and/or form factor) and less expensive than comparable prior-art devices. In addition, a film-assisted molding (FAM) process is not required, thereby reducing the risk of die damage and/or contamination resulting from die-to-film contact. Nor are pre-molded package cavities required. Conventional pick-and-place machinery can be used for some of the steps in the manufacturing of these devices.

By now it should be appreciated that there has been provided an improved packaged semiconductor sensor device and a method of forming the packaged semiconductor sensor device. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the disclosure is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A semiconductor sensor device, comprising:
a substrate;
a pressure-sensing die mounted to the substrate;
pressure-sensitive gel covering at least part of the pressure-sensing die;
a lid mounted to the substrate to form a housing for the gel-covered pressure-sensing die and having an opening that exposes the gel-covered pressure-sensing die to ambient atmospheric pressure outside the sensor device;
at least one other die mounted outside of the housing; and
molding compound encapsulating the at least one other die.

2. The semiconductor sensor device of claim 1, wherein the at least one other die is mounted to the substrate outside of the housing.

3. The semiconductor sensor device of claim 2, wherein the at least one other die comprises a second sensor die mounted directly to the substrate.

4. The semiconductor sensor device of claim 1, wherein the at least one other die comprises a second sensor die mounted to the substrate, and an Application Specific Integrated Circuit (ASIC) die mounted between the pressure-sensor die and the substrate.

5. The semiconductor sensor device of claim 1, wherein:
the at least one other die is mounted on top of the lid; and
the molding compound has an opening that exposes the gel-covered pressure-sensing die to the ambient atmospheric pressure outside of the molding compound.

6. The semiconductor sensor device of claim 1, further comprising:
an Application Specific Integrated Circuit (ASIC) die mounted between the pressure-sensing die and the substrate; and
bond wires electrically connecting the pressure-sensing die and the ASIC die, and the ASIC die and the substrate, and the at least one other die and the substrate.

7. The semiconductor sensor device of claim 6, wherein the pressure-sensitive gel covers the bond wires between the pressure-sensing die and the ASIC die.

8. The semiconductor sensor device of claim 7, wherein the pressure-sensitive gel does not cover the entire wire-bonding between the ASIC die and the substrate.

9. The semiconductor sensor device of claim 1, wherein:
the at least one other die comprises a second sensor die, and an Application Specific Integrated Circuit (ASIC) die mounted between the second sensor die and the substrate; and
wire-bonding between the second sensor die and the ASIC die, between the ASIC die and the substrate, and (iii) between the pressure-sensing die and the substrate.

10. The semiconductor sensor device of claim 9, wherein the molding compound encapsulates the entire wire-bonding between the second sensor die and the ASIC die, and between the ASIC die and the substrate.

11. The semiconductor sensor device of claim 1, wherein the lid has side walls that slant outward.

12. The semiconductor sensor device of claim 1, wherein the at least one other die comprises an acceleration sensor.

13. The semiconductor sensor device of claim 1, wherein:
the pressure-sensing die is mounted to an Application Specific Integrated Circuit (ASIC) die;
the ASIC die is mounted directly to the substrate inside the housing;
the pressure-sensitive gel covers (i) the pressure-sensing die, (ii) all of the wire-bonding between the pressure-sensing die and the ASIC die and (iii) part of the wire-bonding between the ASIC die and the substrate;
the at least one other die comprises a second sensor die mounted directly to the substrate outside of the housing; and
the molding compound encapsulates the second sensor die and is substantially as high as the lid.

14. The semiconductor sensor device of claim 13, wherein the second sensor die is an acceleration-sensing die.

15. The semiconductor sensor device of claim 1, wherein:
the pressure-sensing die is mounted to an Application Specific Integrated Circuit(ASIC) die;
the ASIC die is mounted directly to the substrate inside the housing;
the pressure-sensitive gel covers (i) the pressure-sensing die, (ii) all of the wire-bonding between the pressure-sensing die and the ASIC die and (iii) part of the wire-bonding between the ASIC die and the substrate;
the at least one other die comprises a second sensor die mounted on top of the lid outside of the housing; and
the molding compound encapsulates the second sensor die, is higher than the lid, and has an opening corresponding to the opening in the lid.

16. The semiconductor sensor device of claim 15, wherein the second sensor die is an acceleration-sensing die.

17. The semiconductor sensor device of claim 1, wherein:
the pressure-sensing die is mounted directly to the substrate;
the at least one other die comprises (i) a second sensor die and (ii) an Application Specific Integrated Circuit (ASIC) die mounted between the second sensor die and the substrate outside the housing;
the pressure-sensitive gel covers (i) the pressure-sensing die and (ii) part of the wire-bonding between the pressure-sensing die and the substrate; and
the molding compound encapsulates the second sensor die and the ASIC and is substantially as high as the lid.

18. The semiconductor sensor device of claim 17, wherein the second sensor die is an acceleration-sensing die.

19. A semiconductor sensor device, comprising:
a substrate;
a controller die mounted to the substrate;
a pressure-sensing die mounted to a top surface of the controller die;
pressure-sensitive gel covering at least part of the pressure-sensing die;
a lid mounted to the substrate to form a housing for the controller die and the gel-covered pressure-sensing die, wherein the lid has an opening that exposes the gel-covered pressure-sensing die to ambient atmospheric pressure outside the sensor device;
a second sensor die mounted to the substrate outside of the housing; and
molding compound encapsulating the second sensor die, wherein the pressure sensing die and the second sensor die are in communication with the controller die.

20. A semiconductor sensor device, comprising:
a substrate;
a controller die mounted to the substrate;
a pressure-sensing die mounted to a top surface of the controller die;
pressure-sensitive gel covering at least part of the pressure-sensing die;
a lid mounted to the substrate to form a housing for the controller die and the gel-covered pressure-sensing die, wherein the lid has an opening that exposes the gel-covered pressure-sensing die to ambient atmospheric pressure outside the sensor device;
a second sensor die mounted to an upper, outer surface of the lid, wherein the pressure sensing die and the second sensor die are in communication with the controller die.
